(19) United States
(12) Patent Application Publication
(10) Pub. No.: US 2010/0117203 A1
(43) Pub. Date: May 13, 2010

(54) OXIDE-CONTAINING FILM FORMED FROM SILICON

(75) Inventors: Robert Jeffrey Bailey, Scotts Valley, CA (US); Hood Chatham, Scotts Valley, CA (US); Derrick Foster, Scottsdale, AZ (US); Olivier Laparra, San Jose, CA (US); Martin Mogaard, Scotts Valley, CA (US); Cole Porter, San Jose, CA (US); Taiquing T. Qiu, Los Gatos, CA (US); Helmuth Treichel, Milpitas, CA (US)

Correspondence Address: GIFFORD, KRASS, SPRINKLE,ANDERSON & CITKOWSKI, P.C, PO BOX 7021, TROY, MI, 48007-7021, US

(73) Assignee: Aviza Technology, Inc., Scotts Valley, CA (US)

(21) Appl. No.: 11/668,626

(22) Filed: Jan. 30, 2007

(51) Int. Cl. H01L 29/04; H01L 21/316; H01L 21/26; H01L 21/314

(52) U.S. Cl. 257/627; 438/770; 438/771; 438/762; 257/E29.004; 257/E21.283; 257/E21.328; 257/E21.267

(57) ABSTRACT

A process for forming an oxide-containing film from silicon is provided that includes heating the silicon substrates to a process temperature of between 250° C. and 1100° C. with admission into the process chamber of diatomic reductant source gas Z-Z′ where Z and Z′ are each H, D and T and a stable source of oxide ion. Multiple exhaust ports exist along the vertical extent of the process chamber to create reactant across flow. A batch of silicon substrates is provided having multiple silicon base layers, each of the silicon base layers having exposed <110> and <100> planes and a film residual stress associated with the film being formed at a temperature of less than 600° C. and having a <110> film thickness that exceeds a <100> film thickness on the <100> crystallographic plane by less than 20%, or a film characterized by thickness anisotropy less than 18% and an electrical breakdown field of greater than 10.5 MV/cm.

### FIELD OF THE INVENTION

The present invention in general relates to oxide-containing film formation from silicon and in particular to the formation of such a film having superior electrical properties or reduced residual thermal stress associated with a lower thermal budget.

### BACKGROUND OF THE INVENTION

The formation of an oxide-containing film from a silicon substrate is an important process in the formation of numerous technologically important devices such as integrated circuits, solar cells, and flat panel displays.

Conventional oxide film formation processes are divided into two general categories. The first category is a dry oxidation process in which a silicon substrate is exposed to oxygen, a nitrogen oxide (NOx) at a temperature of more than 900° C. and most often more than 1100° C. to form a film. Limitations associated with this process include kinetically slow film thickness growth, high processing temperature that precludes complex layered substrate usage, a high degree of anisotropy film growth rates based on silicon Miller indices <hkl>, and in the case of NOx oxidants inadvertent nitrogen incorporation in the resultant film.

The other traditional class of oxide film formation process is a wet oxidation in which the oxidant is introduced in combination with steam. The steam is produced by catalytic reaction of hydrogen and an oxidant, plasma discharge in proximity to the reactants, or introduction of a photolysis source. Representative of these efforts are Japanese Patent Publication 405259153A and U.S. Pat. Nos. 6,239,044; 6,335,295 and 6,159,866. Said formation in the presence of steam, commonly referred to as wet oxidation, is characterized by a lower formation temperature of typically between 600 and 1000° C. However, oxidation thickness anisotropy for different crystallographic planes persists as a problem as illustrated in U.S. Pat. No. 6,358,867. Additionally, wet oxidation process still occurs at temperatures that cannot be tolerated by complex structure substrates, as well as growing oxides having electrical breakdown characteristics that are less than desirable.

In recognition of the limitations of conventional wet and dry oxidation processes, attempts have been made to use multiple stage reactions to form oxide-containing films. Representative of these efforts to adjust chemistry and/or temperature between vacuum stages are U.S. Pat. Nos. 6,387,777 and 7,064,084; and U.S. Patent Application Publication 2006/0094254. Unfortunately, such attempts have met with limited success in addressing oxide formation process temperature as being incompatible with various substrates, orientation anisotropy and other limitations associated with traditional wet or dry process while also increasing complexity and diminishing production throughput.

Still another effort to improve oxide film formation has involved the direct delivery of hydrogen and an oxidant into contact with a silicon substrate to create in situ radical formation without resort to a photolysis of plasma source. Representative of such efforts include U.S. Pat. Nos. 6,869,892; 6,599,845 and 7,129,186. However, limitations persist as to the temperature at which oxide film formation occurs and remains in excess of that compatible with a variety of complex silicon substrates, uniformity within a batch of substrate films formed, and the electrical breakdown properties of the resultant oxide-containing films.

Thus, there exists a need for an oxide-containing film batch production process operative at a lower temperature or able to provide superior quality oxide-containing film. Additionally, there exists a need for a batch of silicon substrates containing low thermal residual stress associated with processing at temperature or oxide-containing films having superior breakdown electric field performance so as to enable higher performance devices inclusive of oxide-containing film.

### SUMMARY OF THE INVENTION

A process for forming an oxide-containing film from silicon is provided that includes the evacuation of a process chamber having a vertical extent and containing multiple silicon substrates. The silicon substrates each have reactive surface plane. The process requires heating the silicon substrates to a process temperature of between 250° C. and 1100° C. with the simultaneous admission into the process chamber of the reactants diatomic reductant source gas Z-Z′ where Z and Z′ are each independently H, D and T along the vertical extent of the process chamber; and a stable gas source of oxide ion from a second also along the vertical extent of said process chamber. An optional inert diluent gas is also provided along with the reactants. Multiple exhaust ports exist along the vertical extent of the process chamber through which the reactant chamber reactants pass after exposure to the various reactive surface planes to create an across flow movement of reactants. Holding the silicon substrates in said process chamber at the process temperature for a sufficient amount of time, an oxide-containing film is grown from silicon.

A batch of silicon substrates is provide in a substrate carrier that includes multiple silicon base layers, each of the silicon base layers having exposed <110> and <100> crystallographic planes. A silicon dioxide film is formed from each of the silicon base layers with a residual stress associated with the film being formed at an elevated temperature of less than 600° C. and having a <110> film thickness that exceeds a <100> film thickness on the <100> crystallographic plane by less than 20%.

A batch of silicon substrates is also provide in a substrate carrier that includes multiple silicon base layers, each of the silicon base layers having exposed <110> and <100> crystallographic planes has a <110> film thickness that exceeds a <100> film thickness by less than 18% and the film is characterized by an electrical breakdown field of greater than 10.5 megavolts per centimeter.

### BRIEF DESCRIPTION OF THE FIGURES

FIG. 1 is a cross-sectional view of a batch reactor operative with the present invention to perform radical assisted film formation;

FIG. 2 is a perspective inverted view of an interior portion of a reaction chamber depicted in FIG. 1;

FIG. 3 is a schematic inverted view of a gas inlet arrangement for performance of an inventive process;

FIG. 4 is a schematic flowchart diagram of an inventive process;

FIG. 5 is a time-temperature curve for the formation of a silicon dioxide film in a batch process according to the present invention;

FIG. 6 is a time-temperature curve for the formation of successive silicon dioxide and silicon oxynitride in a batch process according to the present invention;

FIG. 7 is a bar graph depicting batch silicon dioxide film <100> thickness growth and <110> growth rate as a percent increase over <100> as a function of temperature from 350 to 425° C. for equimolar hydrogen and oxygen gas across flow at 0.92 Torr total pressure in 120 minutes;

FIG. 8 is a bar graph depicting batch silicon dioxide film <100> thickness growth and <110> growth rate as a percent increase over <100> as a function of temperature from 450 to 600° C. for equimolar hydrogen and oxygen gas across flow at 0.92 Torr total pressure in 60 minutes;

FIG. 9 is a plot of current density, Jg as a function of applied voltage for silicon dioxide planar films produced at process temperatures of between 450 and 500° C. and ranging in thickness from 44 to 52 Angstroms;

FIG. 10A is a cross-sectional transmission electron micrograph of an STI structure with a satin low-K dielectric cap having a silicon dioxide layer produced according to the present invention using hydrogen and oxygen injected into a batch process reactor. A total process pressure of 1 Torr and a process temperature of 550° C. are maintained for 180 minutes;

FIG. 10B is a magnified view of a cross-sectional transmission electron micrograph of the lower left-hand corner of the micrograph of FIG. 10A;

FIG. 10C is a magnified view of the top central portion of the micrograph depicted in FIG. 10A;

FIG. 11 is a plot of <100> silicon dioxide thickness produced according to the present invention and the increase in oxide thickness for <110> silicon relative to <100> silicon as a function of flow rate of equimolar amounts of oxygen and hydrogen;

FIG. 12 is a cross-sectional transmission electron micrograph of a silicon wafer having an STI structure and exhibiting an oxide formed according to the present invention on both silicon nitride and <110> silicon;

FIG. 13 is a graph depicting <100> oxide thickness formed at 900° C. process temperature from separately injected across-flow streams of oxygen and hydrogen at a reaction pressure of 0.2 Torr, the percent increase in film thickness for <110> silicon dioxide relative to <100> silicon dioxide is also shown with the percent increase of <110> decreasing with increasing total oxide thickness;

FIG. 14 is a plot of current density, Jg as a function of applied voltage for silicon dioxide planar films of varying <100> thickness, Tax produced at 900° C. according to the present invention to determine breakdown voltage BV; and

FIG. 15 is a plot of breakdown field as a function of silicon dioxide film thickness for an inventive substrate batch as compared to conventional high quality oxide formed by dry oxidation.

### DETAILED DESCRIPTION OF THE PREFERRED EMBODIMENTS

The present invention has utility as a process for the deposition of oxide and/or oxynitride films simultaneously on multiple substrates. Uniform reactant introduction and removal throughout a reaction volume allows for batch silicon oxidation to form silicon dioxide or oxynitride films. The films are produced at a lower temperature or are of superior electrical characteristics relative to conventional films.

The present invention has utility in forming oxide-containing films on silicon substrates to produce structures having utility as semiconductors, solar cells, compound semiconductors, flat panel displays, film transistors, industrial xerographic copiers, flexible substrates overlayered with polycrystalline silicon, and MEMS structures. The present invention is particularly advantageous in instances when halogen or carbon contaminants to the oxide-containing film are not desired. Inventive oxide-containing films are produced at heretofore lower temperatures than previously available or of a quality previously not available.

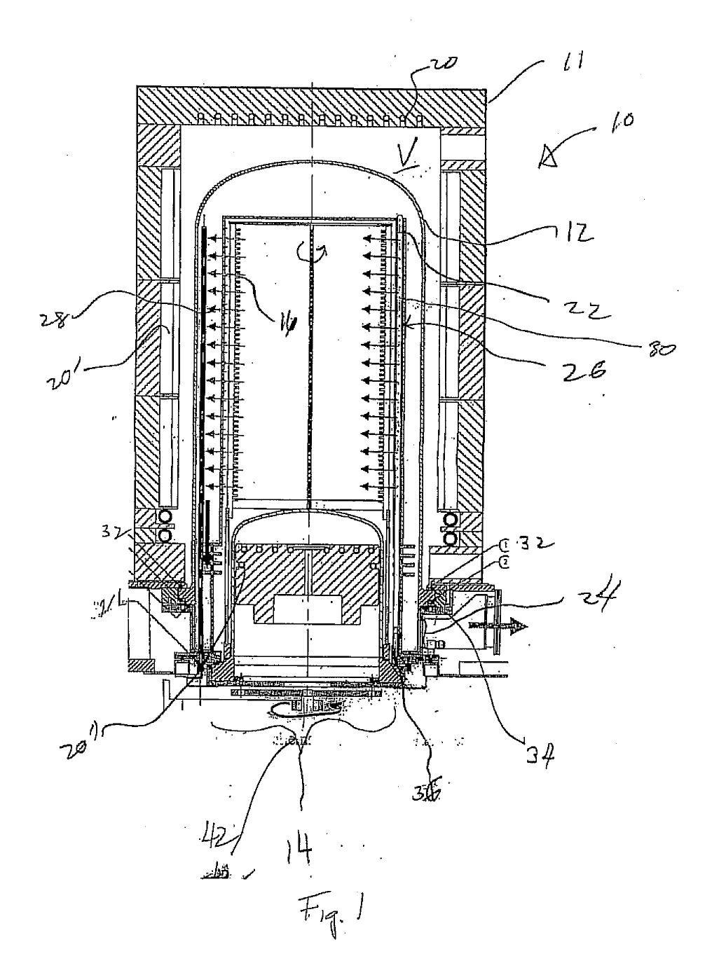

In order to overcome prior difficulties associated with uniform precursor distribution within a batch chamber, a chamber is utilized inclusive of a liner inclusive of elongated tubes including orifices in registry with wafer carrier positions. A series of exit ports formed as slits or apertures create a flow across the multiple wafer surfaces in a laminar flow pattern. Such a reactor is disclosed in WO2005031233 filed Sep. 22, 2004. Such a reactor is currently commercially available from Aviza Technology (Scotts Valley, Calif.) under the trade names RVP 550 and Verano 5500. The exit ports are optionally extended vertically to receive the emission from up to ten orifices and preferably one to five vertically displaced orifices of a given reactant supply. Referring now to FIGS. 1-3, a representative reactor suitable for providing uniform distribution of precursors within a batch reactor chamber is depicted generally at 10.

A vessel 11 that encloses a volume V to form a process chamber 12 having a support 14 adapted for receiving a batch wafer carrier 16 having a number of heating elements, 20, 20′, 20″ (referred to collectively hereinafter as healing elements 112) for raising a temperature of a wafer batch on the carrier 16 to the desired temperature for thermal processing. The reactor 10 optionally includes one or more optical or electrical temperature sensing elements, such as a thermocouple (TIC), for monitoring the temperature within the process chamber 12 and controlling operation of the heating elements 20-20″. Thermal uniformity is thereby achieved along the vertical extent of the carrier 16 when disposed within the process chamber 12. The reactor 10 includes two or more injectors 22, 22′, and 22″ for introducing oxygen gas, a diatomic reductant gas, or an optional diluent into the process chamber 12 for the formation of silicon dioxide or silicon oxynitride film simultaneously on the multiple silicon substrates. It is appreciated that purge fluids are also optionally supplied to the process chamber 12 via any or all of the injectors 22-22″. A purge vent 24 is provided for exhausting the process chamber 12. A liner 26 includes slots 28 preferably in registry with wafer surfaces within a carrier 16 and orifices 30-30″ of injectors 22-22″ as denoted by the fluid flow arrows.

Generally, the vessel 11 has a seal, such as an o-ring 32, to a base-plate 34.

Openings for the injectors 22-22′ are shown at 36, T/Cs and vents are sealed with o-rings, VCR®, or CF® fittings. Fluids released or deposition byproducts created during processing are evacuated through a foreline or exhaust port 42 formed in a wall of the process chamber 12 or in a plenum of the support 14. The process chamber 12 is operated at a pressure between 0.05 Torr and 100 Torr at a variety of temperatures ranging from 250° C. to 1100° C. The reactor 10 is equipped with a pumping system illustratively including a roughing pump; a blower; a hi-vacuum pump; and roughing-, throttle-, and foreline-valves.

The vessel 11 and liner 26 are made of a variety of materials illustratively including metal, ceramic, crystalline or amorphous material that is capable of withstanding the thermal and mechanical stresses of high-temperature and high-vacuum operation, and which is resistant to erosion from gases and vapors used or released during processing. Preferably, the vessel 11 and liner 26 are made from an opaque, translucent, or transparent quartz glass having a sufficient thickness to withstand the mechanical stresses of the thermal processing operation and resist deposition of process byproducts.

Wafers in the carrier 16 are introduced into the reactor 10 through a load lock or loadport (not shown) and then into the process chamber 12 through an opening in the base-plate 34 capable of forming a gas tight seal therewith. In the configuration shown in FIG. 1, the process chamber 12 is a vertical reactor and the access utilizes the movable support 14 that is raised during processing to seal with the base-plate 34, and lowered to enable an operator or an automated handling system, such as a boat handling unit (BHU) (not shown), to position the carrier 16 on the support 14.

The reactor 10 optionally also includes a wafer rotation system 42 that rotates the support 14 and the carrier 16 during processing. Rotating the carrier 16 during processing improves within wafer uniformity by averaging out any nonuniformities in temperature and process gas flow to create a uniform wafer temperature and species reaction profile. Generally, the wafer rotation system 42 is capable of rotating at a speed of from about 0.1 to about 10 revolutions per minute (RPM).

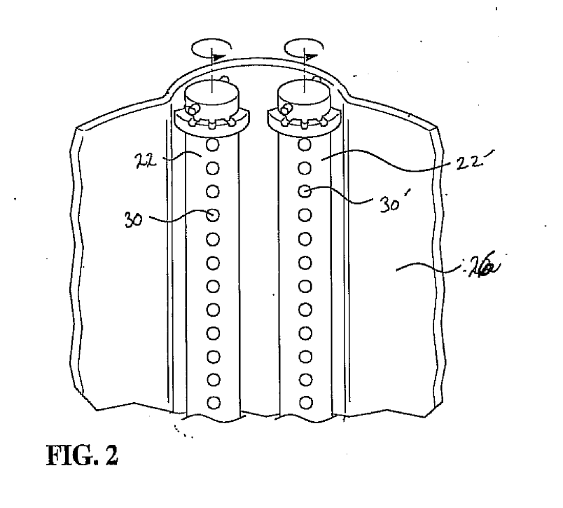

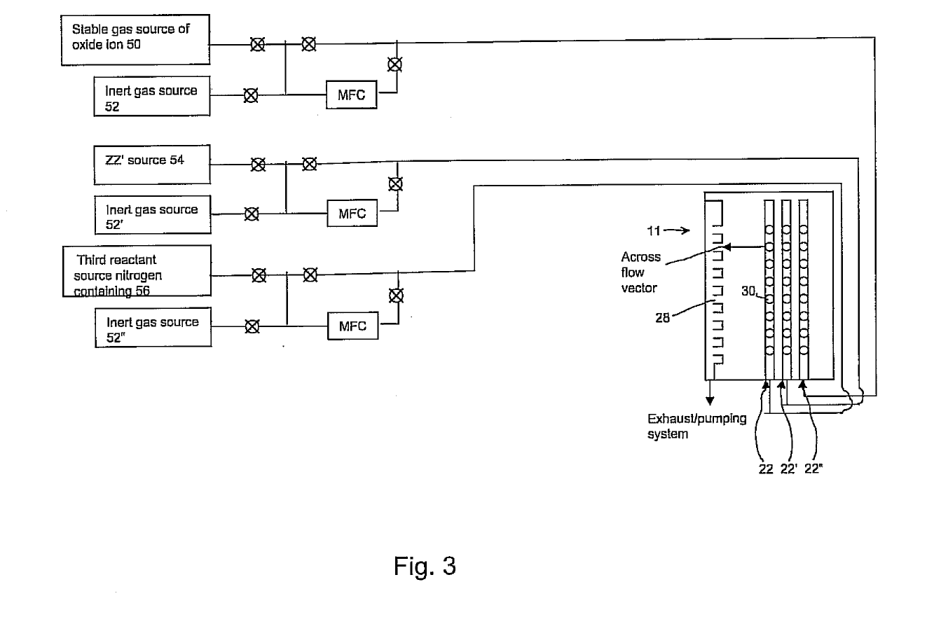

As depicted in FIG. 2, two injectors 22 and 22′ are provided for the delivery of reactants and an optional inert diluent to form an oxide or oxynitride from a silicon substrate reaction simultaneously on a batch of substrates within a reactor 10. Similarly, in FIG. 3, three such reactors 22-22″ are provided. Preferably, an orifice 30 is in registry with wafer surfaces held in position by the wafer carrier 16 as well as with exhaust ports 28 provided in a liner 26 so as to provide a laminar across flow so as to uniformly form oxide-containing films according to the present invention. As depicted in FIG. 2, the relative area of orifices 30′ optionally increase along the length of the injector 22′ in order to account for a pressure drop associated with emission from orifices in closer proximity to an inlet fluid source. Additionally, as shown with reference to injectors 22-22′, the relative diameter of injectors, and the angle defined between a radius of the substrate carrier 16 through the axis of an injector and the vector extending from an injector axis through an emission orifice, and the angle between injectors relative to a substrate carrier center varies between 2 and 180 degrees and are independently variable. Optionally a second or more courses of exhaust ports 28′ are provided in the liner. Preferably the injectors, orifices therein and exhaust ports are positioned to provide and maintain reactant flow across a silicon substrate surface and reaction conditions that are substantially uniform through the vertical extent of the liner 26. With regard to the gas emission angle so defined, any angular value is available as each injector is independently rotatable around a longitudinal axis. Preferably, each injector is rotatable 360 degrees about the injector longitudinal axis. An indexing pin 45 associated with an injector identifies the angular position relative to an aperture in which it seats within the reactor 10.

In contrast to the present invention providing movement of reactants flowing across a silicon substrate, prior art reactors as embodied in U.S. Pat. No. 7,129,186 offer a reactant path of least resistance past a substrate edge to an exhaust outlet positioned vertically above a wafer carrier. This reactant path of least resistance limitation of the prior art is exacerbated when hydrogen is a reactant and has a property to rise in a vertical volume.

An exemplary gas flow schematic for a three injector reactor is depicted in FIG. 3. A stable gas source of oxide ions 50 is provided in fluid communication with injector 22 within vessel 11. An inert gas source is optionally interconnected to injector 22. With the use of conventional valves a mass flow controller (MFC) both source 50 and 52, or either source alone are selectively fed to the vessel 11 by injector 22. With registry of a silicon substrate surface and an exhaust slot an across flow of reactants with a high degree of uniformity on a given wafer surface and vertically displaced wafers is achieved. In a similar manner, a stable diatomic reductant ZZ′ source gas 54 alone, an inert diluent gas source 52′, or a combination thereof are selectively metered to injector 22′. A third nitrogen containing reactant gas source 56 such as an oxide ion source of nitrous oxide or nitric oxide, ammonia or deuterated ammonia is also optionally introduced to facilitate silicon oxynitride growth through injector 22″. It is appreciated that as with conventional gas connection schemes, inert gas sources 52′ and 52″, are optionally each independently is supplied by inert gas source 52. It is further appreciated that flowing inert gas through an injector when a reactant is not being provided through that injector tends to inhibit backflow into the unused injector.

In inventive embodiments inclusive of only two injectors 22 and 22′, gas feed interconnection is provided for the third reactant 56 to a first injector 22 or second injector 22′. Ideally a NOₓ third reactant is supplied with oxygen and ammonia or deuterated ammonia is supplied with ZZ′. Inert gas is supplied simultaneously and or separately with reactants 52, 54, or 56. Alternatively, some or all of the stable diatomic reductant source gas is premixed with the stable gas source of oxide ion with the proviso that delivery pressure of a mixed reactant flow is below the explosion threshold.

An inventive process for film formation simultaneously on multiple silicon substrates includes loading multiple substrates within a reactor and purging the reactor with an inert fluid and evacuating the reactor. It is appreciated that the reactor is either maintained at deposition temperature prior to a substrate stack loaded and a substrate carrier being loaded therein, or alternatively, the reactor is brought to deposition temperature subsequent to evacuation.

The present invention introduces a stable gas source of oxide ion and a stable diatomic reductant source gas Z-Z′ into a reaction chamber to provide a path of least resistance for reactants over a silicon substrate surface, where Z and Z′ are each independently H, D and T. The stable diatomic reductant source gas is H₂, D₂, HD or T₂. The stable diatomic reductant gas sources having a molecular weight of greater than 2 atomic mass units are used according to the present invention to particular advantage in having kinetics and molecular weight differences relative to the stable gas source of oxide ion favorable to either low temperature film formation or formation of superior quality films relative to those previously available. In order to form a silicon dioxide film, the stable gas source of oxide ion is oxygen gas. As the stable diatomic reductant source gas and the stable gas source of oxide ion are not catalytically combusted prior to or internal to the reaction chamber through resort to a catalyst, plasma generator or photolysis source, it is believed, without intending to be bound by a particular theory that oxide formation occurs through the reaction of highly oxidizing radical species of oxygen that react with diatomic reductant source gas and is hypothesized to occur through the formation of five intermediate species of O, Z, OZ, ZO₂ and Z₂O₂ where Z is H, D, T or combinations thereof. Without intending to be bound by a particular theory, Z₂O is believed to play an inconsequential role in oxide-containing film formation according to the present invention based on the ability of the present invention to form oxide-containing film at lower temperatures than attainable through wet oxidation process, as well as with a lower degree of film deposition rate dependency on silicon crystallographic plane.

Factors relevant to increasing the rate of oxide-containing film formation include reaction temperature, reaction pressure, reactant resonance time in proximity to a silicon substrate, ratio of stable diatomic reductant source gas and stable gas source of oxide ion, and diatomic reductant source gas molecular weight all while maintaining a balanced across-flow injection and exhaust of gases flowing across a silicon substrate.

A stable gas source of oxide ion as used herein is defined to include a molecule thermodynamically favored in equilibrium at a film formation temperature relative to other species generated from a pure source of stable gas source of oxide ion. Representative stable oxide ion gas sources include molecular oxygen, nitrous oxide, and nitric oxide. Preferably, the stable gas source of oxide ion is molecular oxygen in instances when a silicon dioxide film formation is desired absent inadvertent nitrogen inclusion.

Formation of a silicon oxynitride occurs through the simultaneous introduction into an inventive across-flow reactor of molecular oxygen, a stable diatomic reductant source gas Z-Z′, and a nitrogen source of nitrous oxide, nitric oxide, ammonia, deuterated ammonia, or combinations thereof. In a two injector reaction chamber according to the present invention, preferably the nitrogen source and diatomic reductant source gas Z-Z′ are introduced through one injector while molecular oxygen is introduced through the second injector. The present invention provides as a result of across-flow movement of reactants a reduced temperature of oxynitride film formation as well as film deposition rate independence on silicon crystallographic plane orientation relative to conventional silicon oxynitride formation processes. It is appreciated that a silicon dioxide film is readily formed according to the present invention on a silicon substrate and through injection of different reactants as detailed above in an across-flow configuration, an oxynitride film is readily formed over the silicon dioxide film without removing the silicon substrates from the reaction chamber or appreciably changing reaction temperature. According to the present invention, silicon dioxide and silicon oxynitride sequential film formation occurs on silicon substrates at reaction temperatures that vary by less than 300° C. and preferably by less than 200° C. These temperatures are considered to be less than an appreciable temperature change.

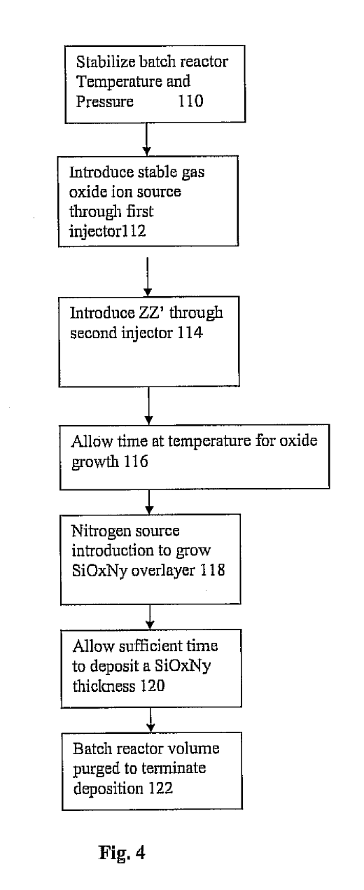

Referring now to FIG. 4, a schematic of an inventive process is provided. Temperature and pressure within a batch reactor loaded with a substrate carrier including multiple silica substrates is stabilized at step 110. Temperature stabilization is performed through use of heating elements and feedback control with temperature sensors dispersed within the reactor. Pressure stabilization results after reactor evacuation and backfill with an inert fluid. Depending on the nature of the film deposited, inert fluids illustratively include nitrogen, helium, argon, krypton and xenon. Typically, the temperature is stabilized between 250 and 1100° C. although most film formations of commercial interest occur between 300° C. and 950° C. Pressure stabilization for all gases at deposition temperature typically is between 0.001 Torr and 100 Torr with most film deposition reactions of commercial interest occurring between 0.05 Torr and 10 Torr.

A stable gas source of oxide ion, preferably molecular oxygen, is introduced into the batch reactor through an injector 112. The introduced stable gas source of oxide ion flows across vertically displaced silicon substrates within the batch reactor. In concert with or subsequent to step 112, diatomic reductant source gas Z-Z′ where Z and Z′ are each independently H, D or T are introduced into the reactor 114. Preferably, the diatomic reductant source gas Z-Z′ is delivered to the reactor through an injector different than that used to provide the stable gas source of oxide ion to the reactor.

The silicon substrates within the batch reactor are allowed to remain in contact with the stable gas source of oxide ion and diatonic reductant source gas Z-Z′ at a reaction temperature for a time to grow a desired thickness silicon dioxide at step 116. A nitrogen deposition source is then optionally introduced into the batch reactor at step 118 by way of an across-flow positioned injector if the growth of a silicon oxynitride overlayer is desired. After allowing sufficient time to form a film thickness at step 120, the batch reactor volume is purged to terminate oxide-containing film formation at step 122.

The partial pressure of the stable gas source of an oxide ion is varied between 0.01 and 50 Torr within the process chamber. Preferably, the partial pressure of the stable gas source of oxide ion is oxygen gas and the partial pressure is between 0.1 and 9 Torr. Most preferably, the partial pressure of oxygen gas in the process chamber is between 0.2 and 2 Torr.

The partial pressure of the diatomic reductant source gas Z-Z′ is varied between 0.01 and 50 Torr within the process chamber. Preferably, the partial pressure of the diatomic reductant source gas Z-Z′ is oxygen gas and the partial pressure is between 0.1 and 9 Torr. Most preferably, the partial pressure of oxygen gas in the process chamber is between 0.2 and 2 Torr.

The molar ratio of diatomic reductant source gas Z-Z′ to stable gas source of oxide ion varies between 0.1:1 and 4:1, and preferably is between 0.5 and 2:1.

The present invention provides a silicon substrate with an oxide-containing film formed with a residual stress associated with silicon dioxide or silicon oxynitride film being formed at a temperature of less than 400° C. and preferably with a residual stress associated with the film being produced at an elevated temperature of between 325 and 390° C. An oxide-containing film on a substrate having a residual stress associated with being heated to less than 400° C. according to the present invention is also characterized by a variation in film thickness between <110> and <100> faces being less than 18% in film thickness, a within-wafer nonuniformity of less than 1% 3 σ and a wafer-to-wafer (WTW) variation of less than 1% 1 σ for wafers displaced vertically within a process reactor by 100 centimeters, the vertically displaced wafers each being provided with across flow of reactants with corresponding registered injector orifices and exhaust ports along the vertical extent of the process chamber with an exhaust port intersecting the pitch of from 1 to 5 silicon substrates within a substrate carrier. In order to achieve maximal deposition rates, preferably the total process chamber pressure during oxide-containing film formation is less than 10 Torr and more preferably between 0.05 and 1.5 Torr. Still more preferably, the diatomic reductant source gas Z-Z′ is provided in a molar ratio to molecular oxygen of roughly 1:1. It is noted that in situ steam generation affords no reaction to produce silicon dioxide at temperatures of below 400° C. nor do other prior art radical assisted oxidation procedures. Without intending to be bound to a particular theory, it is believed that radical concentrations associated with reactant interaction at film deposition temperature are feasible because of the across-flow movement of the reactants across a silicon substrate and the removal of reaction byproducts through exhaust ports vertically extending along the process chamber. Still another advantage of the inventive process and the resulting batch of oxide film containing silicon substrates is the lack of impurities associated with conventional chemical vapor deposition silicon dioxide formation where common impurities include halogens such as fluorine and chlorine, and carbon.

The present invention provides batch oxide-containing film growth at temperatures at which no other known method is capable of forming an oxide-containing film on a silicon substrate. The present invention also has the general characteristic of producing a film of comparable quality to that produced by conventional wet oxidation techniques yet at a reduced temperature and having characteristics of reduced silicon crystallographic face dependent anisotropic deposition, improved within-wafer (WIW) variation, reduced wafer-to-wafer variation within a batch, and production at a temperature typically 1 to 300° C. less than the comparable wet oxidation process to achieve the same rates of silicon dioxide formation. While conventional wet and thermal oxidation processes have oxidation rate differences between <100> and <110> silicon surfaces of between 60 and 130%, the process of the current invention results in anisotropic oxidation rate differences that typically vary between 3 and 20 thickness percent. Additionally, the present invention achieves silicon dioxide formation on a silicon substrate at a lower temperature compared to known radical oxidation processes such as those detailed in U.S. Pat. Nos. 6,869,892 and 7,129,186 along with providing superior wafer-to-wafer uniformity.

An attribute of the present invention in which oxide-containing film formation occurs at temperatures of between 800 and 1100° C. is the formation of a batch of silicon substrates having a silicon dioxide film having electrical properties previously unattainable. An inventive batch of silicon dioxide film coated silicon substrates are formed in this temperature range that have breakdown voltages that are typically more than 20% and often 30% higher than the best dry oxidation formed silicon dioxide, as well as occurring at temperatures that are often several hundred degrees centigrade lower, and typically lower by between 100 and 300° C. Based on measurement of breakdown voltage for batch silicon dioxide film thicknesses of from 10 to 500 Angstroms and leakage current for silicon dioxide film thicknesses of from 10 to 100 Angstroms, it is possible to generate a plot of breakdown electric field that for silicon dioxide films produced according to the present invention is greater than 10.5 Megavolts per centimeter (MV/cm) and typically in the range of 10.5 to 15 MV/cm. Batch silicon dioxide electrical breakdown field values of between 10.8 and 11.6 MV/cm are readily attained at equimolar Z-Z′:O₂ flow at 900° C. with variation in reactant flow rate and total pressure. In contrast to the present invention, conventional high temperature oxides typically have a breakdown electric field in the range of 6 to 8 MV/cm. In calculating breakdown electric field it is appreciated that the voltage contribution of the probe work function difference, V_{WF} between the probe and the silicon bulk and the silicon surface potential, V_{Si} provide a non-negligible error as the film thickness decreases, especially in the range of from 10 to 200 Angstroms. The measured voltage is a sum of the actual value of the oxide voltage Vox, V_{WF} and V_{Si}. V_{WF} and V_{Si} are first estimated and subtracted from the measured voltage. V_{WF} is estimated by first substituting a material with a predetermined known work function such as gold or graphite in place of a silicon substrate and measuring the voltage. V_{Si} is estimated from a surface photovoltage measurement with a high light intensity source such as a xenon flash lamp. Surface photovoltage measuring devices are well known in the art. For a given value of surface photovoltage and a reasonably estimated value of excess optically induced carrier generation, an approximate corresponding value of V_{Si} can be calculated from a theoretical model. E. O. Johnson, Phys. Rev., 111(1) pp. 153-166 (1958). The first order effect in the model is that the magnitude of surface photovoltage approaches V_{Si} and the optically induced carrier generation is comparable to and larger than the silicon doping concentration. Additionally, the optically induced carrier generation is also readily approximated by this model through a surface photovoltage measurement in strong accumulation and in strong inversion modes.

To illustrate the importance of V_{WF} and V_{Si} correction in thinner silicon dioxide films, in a 2000 Angstrom oxide, work function and silicon surface potential constitute less than 1% error in calculating breakdown electric field while for a 50 Angstrom oxide the error associated with V_{WF} and V_{Si} these values become non-negligible. Compensating for potential associated with work function and the silicon surface provides a breakdown field for silicon dioxide formed according to the present invention at a temperature above 800° C. of more than 11 MV/cm.

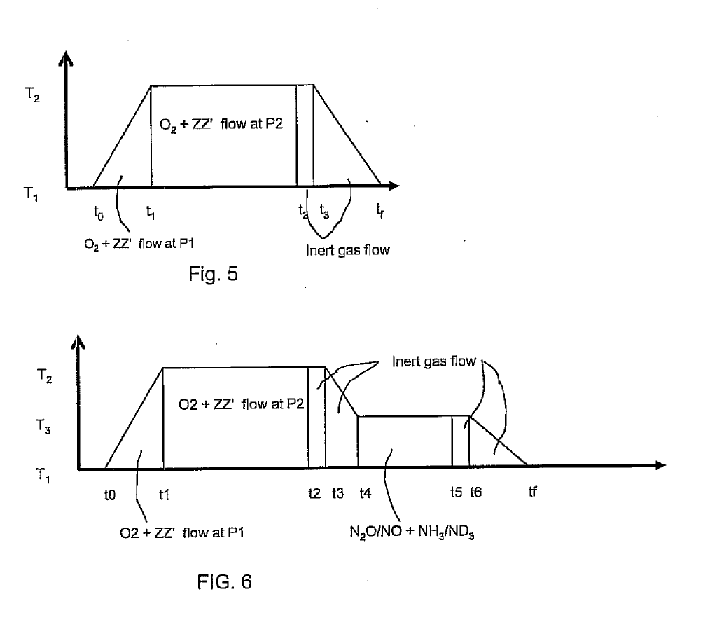

Referring now to FIG. 5, the process steps for the formation of a high quality silicon dioxide film is provided with reference to a time-temperature curve to which the batch of silicon substrates is exposed. During an initial ramp-up period silicon substrates t₀-t₁ are loaded into the process chamber at a first temperature and ramped to a higher second temperature. As shown in FIG. 5, the temperature ramp is linear as a function of time. According to the present invention, the diatomic reductant source gas Z-Z′ and the stable gas source of oxygen ion, namely molecular oxygen, are flowing at a rate to create a thin oxide film during the course of ramp-up. The thickness of the oxide film formed during ramp-up is typically between 5 and 50 Angstroms and preferably between 8 and 20 Angstroms so as to prevent a visually discernable hazing to a silicon substrate with subsequent addition of thicker oxide.

Preferably, silicon oxidation is suppressed through the lack of reactant injection into the process chamber between T₁ and T₂ of FIG. 5 at a total reactant pressure P₁ of between O and P₂. The initial ramp-up starting temperature T₁ at which oxidation is initiated is selected to limit the density of stress-induced defects and residual thermal stress within the thin oxide grown during ramp-up. Typical ramp-up rates range from 0.5 to 50° C. per minute and the molar ratio of diatomic reductant source gas Z-Z′ to stable gas source of oxide ion, preferably where the stable gas source of oxide ion is oxygen, is from 3:1 to 0.5:1 and preferably less than 1:1. [Please confirm.]

Subsequent to the ramp-up portion of the time-temperature curve, the batch of silicon substrates are exposed to a steady-state temperature that is higher than the initial temperature at which the substrates were loaded, t₁-t₃ and at an optionally different total pressure P₂. The plateau temperature to form silicon dioxide films having a higher breakdown field than those formed by conventional techniques occurs at a temperature, T₂ of between 800 and 1100° C. It is appreciate that oxide-containing films are readily grown at temperatures T₂ as low as 250° C. At T₂, the rate of oxide-containing film formation is increased provided that the ratio of reactants and total process chamber pressure is maintained. According to the inventive process, the rate of oxide formation decreases with increasing total partial pressure of reactants above about 2 Torr, and with decreasing partial pressure of diatomic reductant source gas Z-Z′.

In the final phase of the time-temperature oxide-containing film formation, and with a desired film thickness, the reactant flow to the process chamber is shut off and an inert diluent is flowed through the injectors t₂-t₃ at T₂ while the process chamber temperature is ramped down T₂-T₁ during t₃-t_{f} to a desired terminal temperature at a given rate before the process chamber is opened and the substrate carrier removed. While the ramp-up and ramp-down are depicted as linear profiles, it is appreciated that other ramp-down profiles are readily applied to each illustratively including stepped, exponential, polynomic, and combinations thereof.

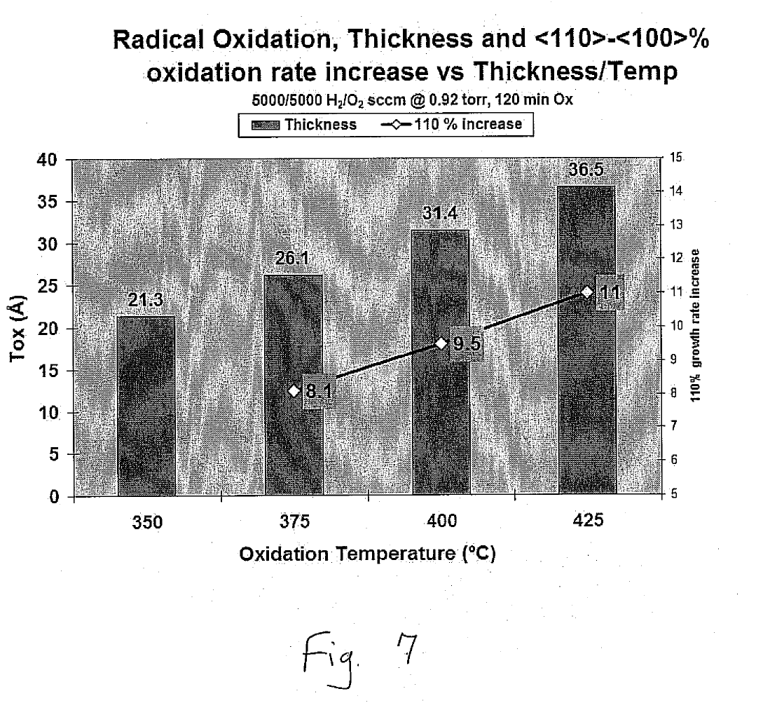

Silicon oxynitride is also readily formed on top of a silicon dioxide layer formed according to the time-temperature curve of FIG. 5 and applied on top of a silicon dioxide layer through repeating a cycle of the time-temperature curve t₄-t₆ with the proviso that some or all of the stable gas source of oxide ion is nitrous oxide or nitric oxide, alone or in combination with ammonia or deuterated ammonia as shown in FIG. 6 where like symbols t and T correspond to those detailed in FIG. 5. Alternatively, T₂=T₃ and at t₂ molecular oxygen flow through an injector is discontinued and replaced with a nitrogen oxide (N₂O or NO) flow alone or in combination with ammonia or deuterated ammonia, at t₄. As a result, the present invention through the use of across flow allows for the formation alone or in combination with Z-Z′ of silicon dioxide with a silicon oxynitride overlayer without removing the silicon substrate batch from the process chamber. Preferably, an inert diluent purge is provided at plateau temperature T₂, t₂-t₃ intermediate between silicon dioxide and silicon oxynitride formation regardless of the relative values of T₂ and T₃. To promote substrate throughput, preferably, silicon oxynitride is formed at the same plateau temperature as the silicon dioxide (T₂=T₃). However, it is appreciated that variation in silicon oxynitride film formation temperature (T₃> T₂ or T₂>3) and total reaction chamber pressure are also operative herein. A graphical representation of a combined silicon dioxide and silicon oxynitride time-temperature curve having a silicon oxynitride formation temperature plateau different than that for silicon dioxide is provided in FIG. 6.

The present invention is further detailed with respect to the following nonlimiting examples which are intended to illustrate particular embodiments and practice parameters for the present invention. These examples are not intended to limit the scope of the appended claims.

### Example 1

A stack of 200 mm silicon wafer substrates are loaded into a substrate carrier introduced into a reactor as detailed with respect to FIGS. 1 and 2. The process temperature is brought to a plateau value and maintained while the reactor has an internal oxygen concentration of less than 10 parts per million and is continuously purged by nitrogen gas. The reactor is evacuated to a base pressure of 0.03 Torr with multiple pumping stages that provide slower pumping at higher pressures and faster pumping as lower internal pressures are obtained. Upon stabilizing the pressure at 0.03 Torr, the gate valve is closed and a chamber leak check is performed. Oxygen gas is introduced through a first injector at a rate of 5000 sccm. Hydrogen gas flows into the reactor through a second injector at a rate of 5000 sccm to yield a total reactor pressure of 0.92 Torr and held at process temperature for 120 minutes, Silicon dioxide of a <100> thickness and a <110> silicon crystallographic plane growth rate thickness increase relative to <100> plane growth rate is grown, as shown in FIG. 7 for substrate batches processed at plateau process temperatures of 350, 375, 400 and 425° C. Over the process temperature range <100> oxide thickness increased from 21.3 to 36.5 Angstroms while <110>% thickness increase relative to <100> growth increased from 8.1 to 11%.

### Example 2

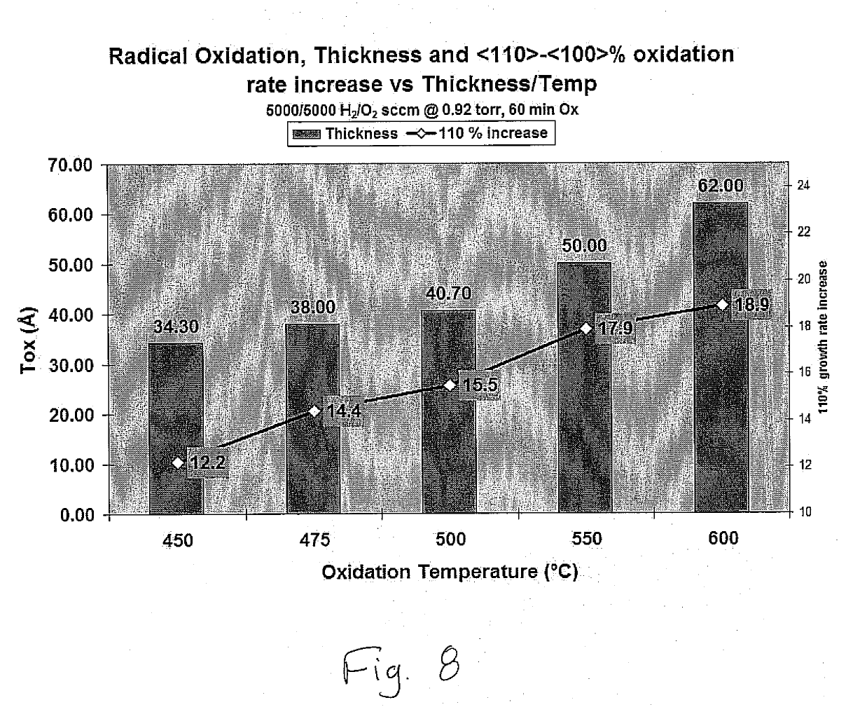

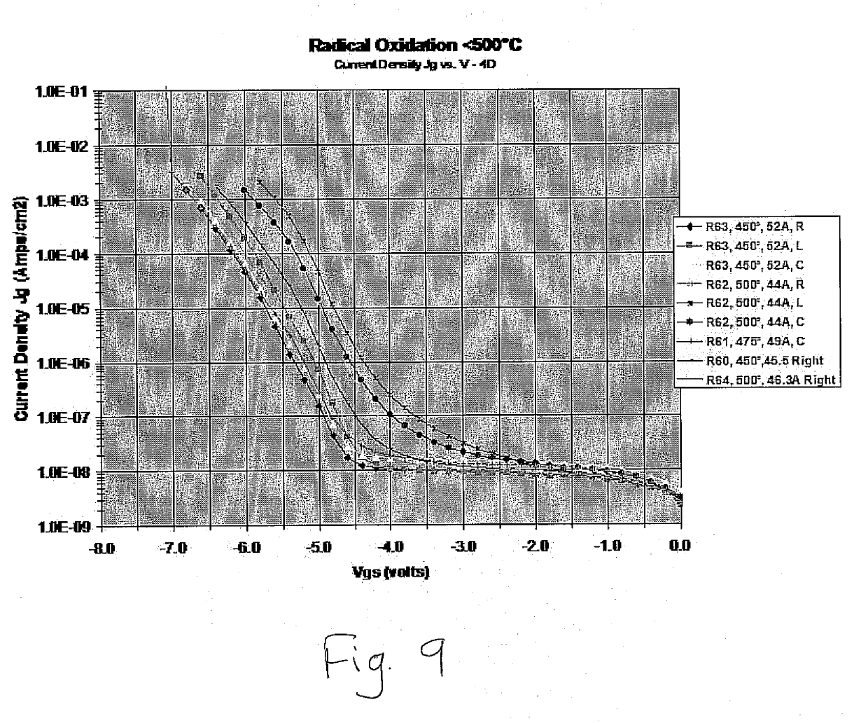

The process of Example 1 is repeated for individual batches of wafers each being processed at process plateau temperatures of 450, 475, 500, 550 and 600° C. The process temperature is maintained for 60 minutes as opposed to 120 minutes used for Example 1. Over this process temperature range and oxidation time, <100> oxide thickness increased from 34.3 to 62 Angstroms while <110>% increase relative to <100> growth increased from 12.2 to 18.9%, as shown in FIG. 8.

### Example 3

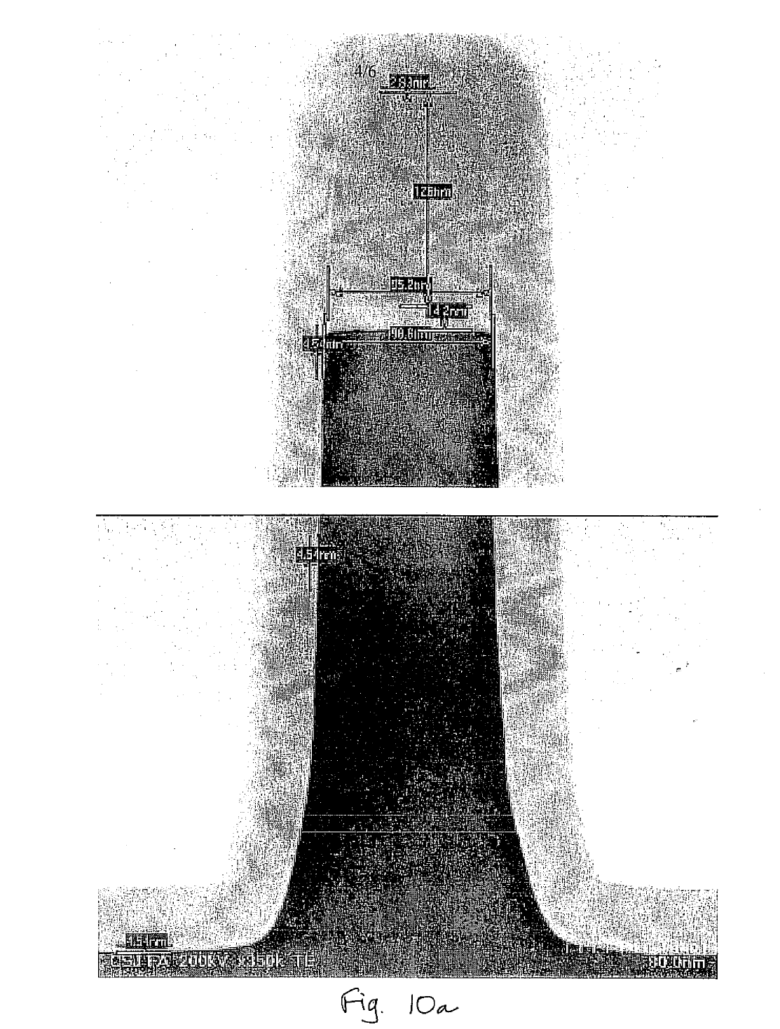

Silicon dioxide films produced on planar silicon wafer substrates according to Example 2 were measured to determine current density Jg as a function of applied voltage (voltage −4 D). A plot of leakage current as measured for 5 wafers designed R60-R64 is provided in FIG. 9 where the process temperature is noted in degrees centigrade, the silicon dioxide film thickness is provided in Angstroms where “A” is used as symbolic of Angstroms and the following letter R, L or C denotes relative position of current density measurement as a function of applied voltage (V −4D) corresponding to right, left and center, respectively, relative to an index in wafer notch. As FIG. 9 makes clear, leakage characteristics of silicon dioxide produced according to the present invention appears to be thickness dependent yet independent of the process plateau temperature T₂ at which the silicon dioxide was formed.

### Example 4

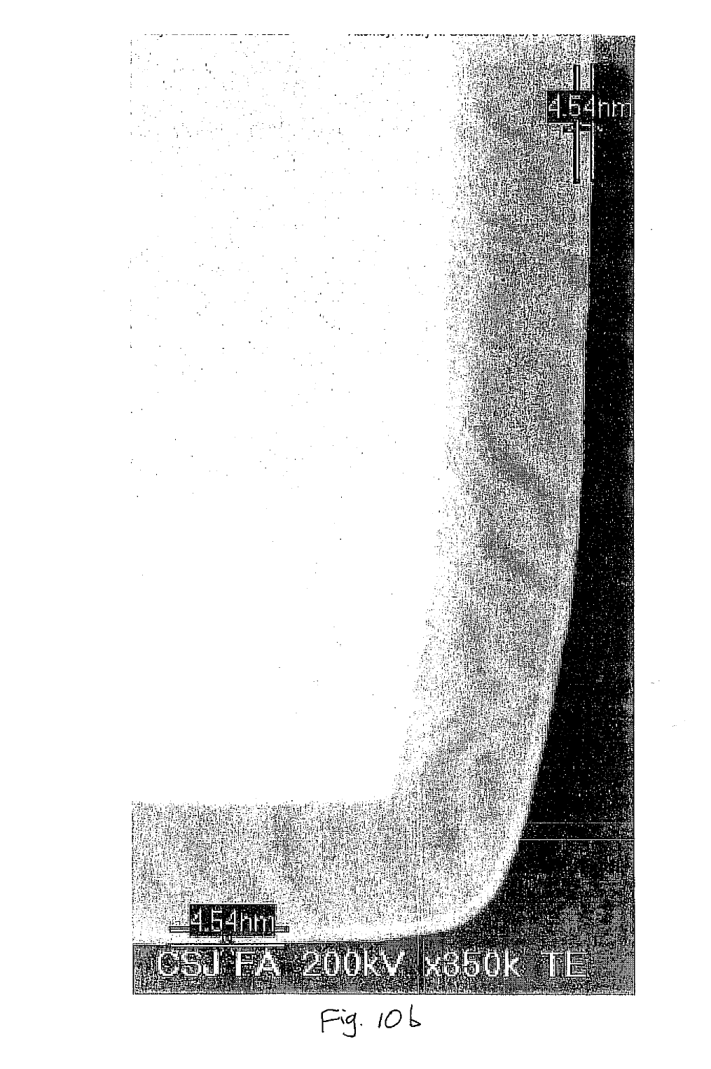

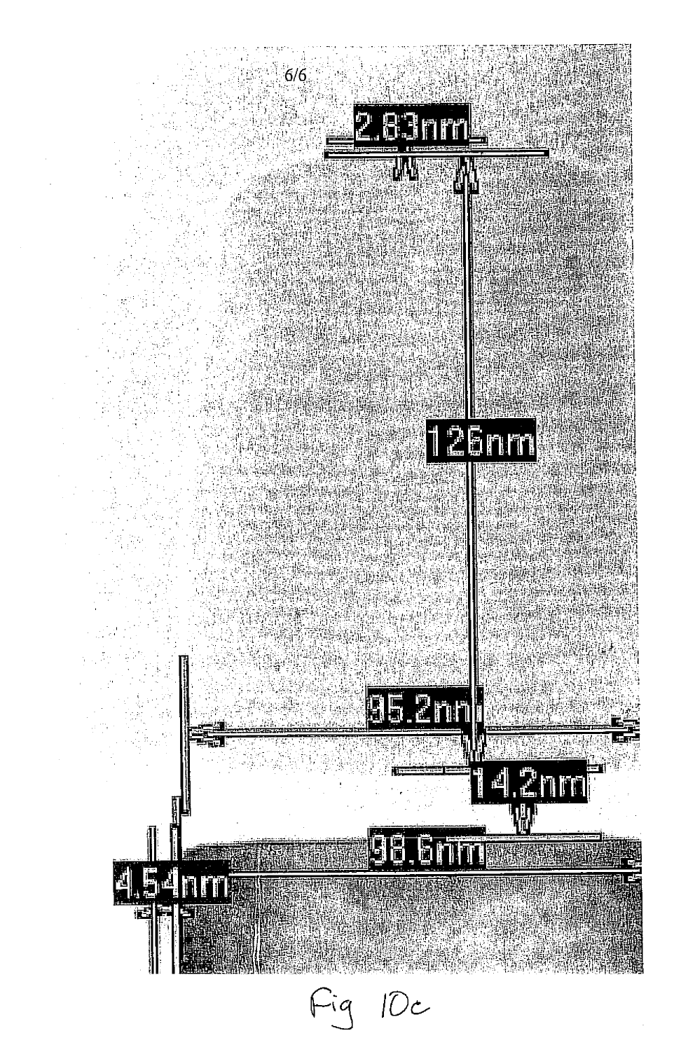

The process of Example 1 is repeated with hydrogen and oxygen gases each flowing into a process reactor through separate injectors at 200 sccm each across substrate surfaces to provide a total pressure at process temperature of 1 Torr. The process temperature for silicon dioxide formation is increased to 550° C. with reactant gas flow maintained at a process temperature of 550° C. for an oxidation time of 180 minutes. A first wafer having an STI structure with a SiN cap after processing was cross sectioned and examined by transmission electron microscopy and imaged at 200 kilovolts. A 45 Angstrom thick conformal growth on trench wall, bottom quarter and floor is noted in FIGS. 10A and 10B while a 28 Angstrom silicon dioxide layer is grown on an adjacent DCS-silicon nitride underlying structure, also coated with a SiN cap as shown in FIGS. 10A and 10C. Within the same batch as the silicon substrate depicted in FIGS. 10A-10C, planar substrates are also provided of 200 millimeter wafers of polysilicon, DCS-silicon nitride blanket coated wafers and a clean <100> silicon substrate, Oxide-containing film formation at 550° C. for 180 minutes provided an oxide film thickness of 57.7 Angstroms for polycrystalline silicon, an oxide thickness of 22 Angstroms on silicon nitride, and an oxide thickness of 41.5 Angstroms for a <100> silicon substrate (results not shown).

### Example 5

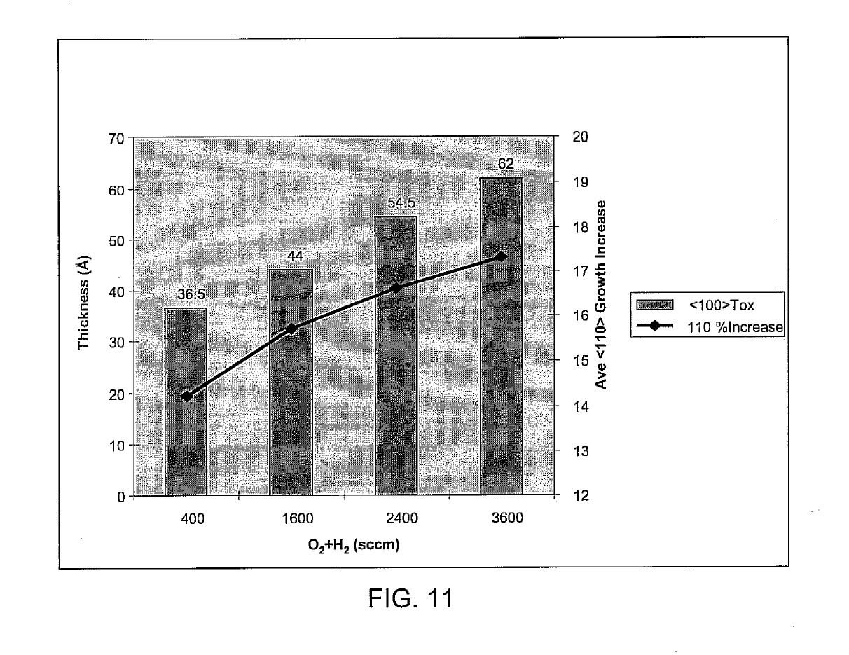

The process of Example 1 is repeated for a batch of 200 millimeter silicon wafers contoured to expose <110> and <100> silicon crystallographic planes. In contrast to the process of Example 1, the process temperature is held at 600° C. and the substrates are subjected to oxide-containing film forming reactants for 150 minutes with a molar ratio of hydrogen:oxygen maintained at 1:1 while the total flow rate of reactant gases was varied between four separate batches from between 400 sccm to 3600 sccm. The resultant <100> silicon dioxide film thickness and percent increase in <110> oxide growth rate relative to oxide growth rate on <100> silicon is provided as a function of flow rate in FIG. 11.

### Example 6

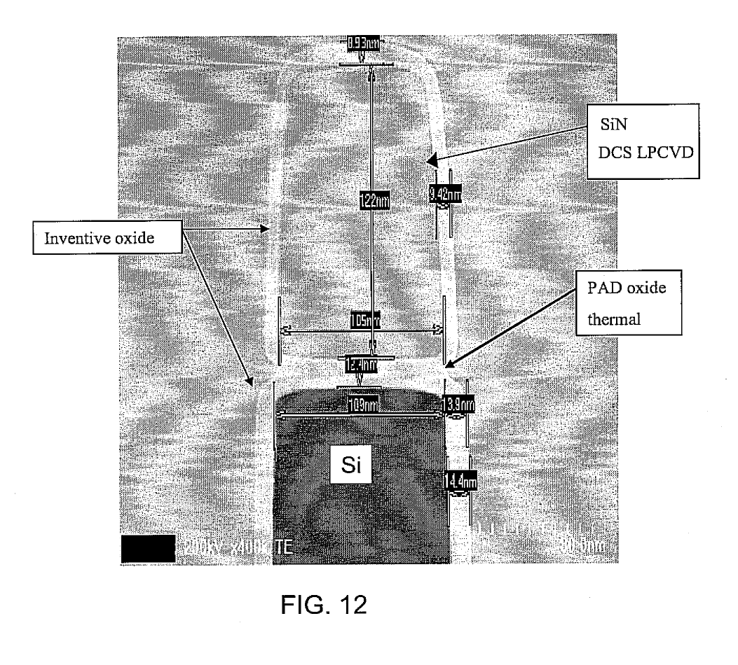

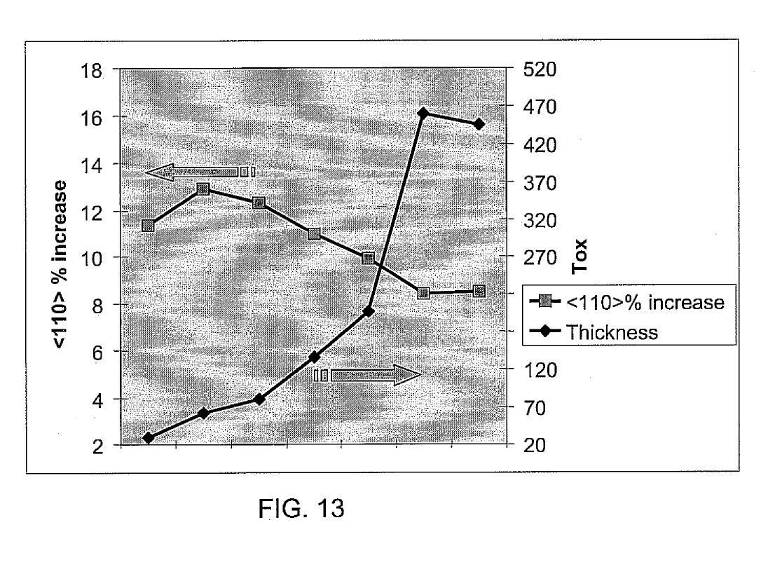

The process of Example 5 is repeated with the process temperature being increased to 750° C. using a silicon substrate having an STI structure. After processing, the wafer is subjected to cross-sectional transmission electron microscopy at 200 kilovolts as shown in FIG. 12. A 94 Angstrom thick silicon dioxide layer is noted on the silicon nitride portion of the STI structure while a 144 Angstrom thick oxide is observed on silicon <110>. Effectively identical results are noted for wafers placed 50 wafer positions above and 50 wafer positions below that depicted in FIG. 12.

### Example 7

A stack of 200 millimeter silicon wafer substrates having exposed <100> and <110> silicon crystallographic planes is loaded into a substrate carrier and placed into a process reactor detailed with respect to Example 1. Oxygen gas and hydrogen gas flow through separate injectors to yield a total reactor pressure of 0.2 Torr and held at a process temperature for varying amounts of time to produce <100> silicon dioxide films of a thickness ranging from 25 to 470 Angstroms. The rate of silicon dioxide growth is approximately 2.5 Angstroms per minute. [Please confirm.] A measurement of silicon dioxide thickness on <110> silicon faces indicates that the percent increase in <110> oxide thickness relative to <100> oxide thickness decreases with increasing silicon dioxide thickness, as shown in FIG. 13. A smaller differential between the oxide thicknesses on <110> and <100> silicon faces is noted for the present invention relative to conventional wet and dry oxidation processes as well as an increase in orientation in dependence of oxide film thickness increasing with film thickness.

### Example 8

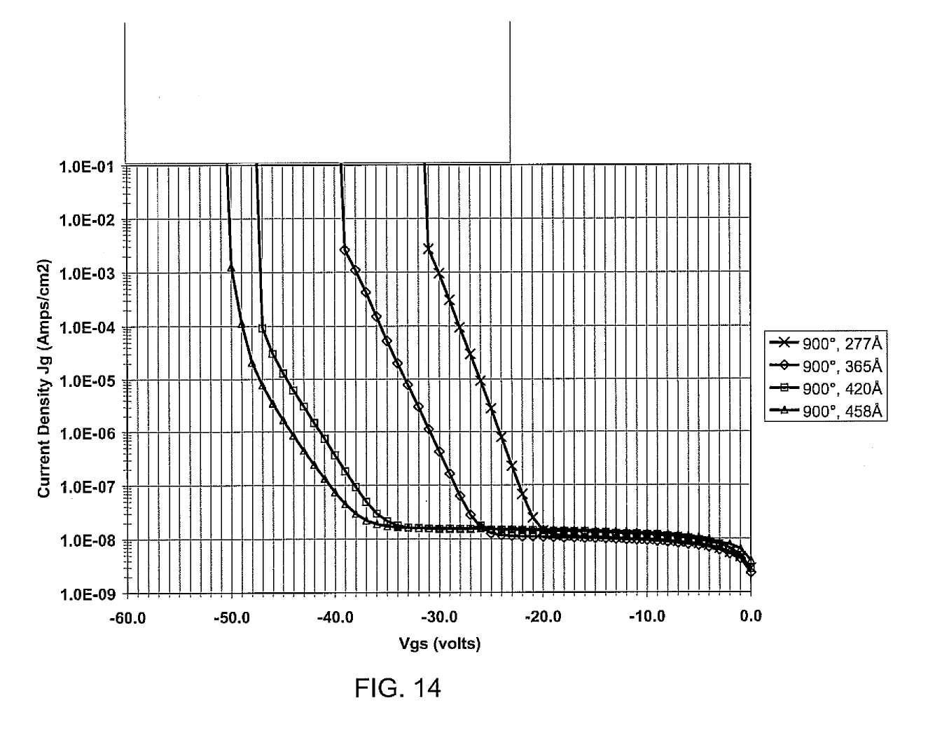

The electrical characteristics of silicon dioxide films produced according to the process of Example 7 are measured to determine current density as a function of applied voltage (voltage −4D) to determine leakage current for thin films and breakdown voltage for thicker films. The breakdown voltages (in Volts) for <100> silicon dioxide film thicknesses (Tox) of 277, 365, 420 and 458 Angstroms are provided in FIG. 14 where each current density-voltage curve shown in FIG. 14 is an average of left, right and center data collection for each wafer substrate. A summary of relevant values obtained from FIG. 14 is provided in Table 1 along with data obtained from conventional dry oxidation produced silicon dioxide films.

TABLE 1
Summary of breakdown voltage data for silicon dioxide films
formed by the present invention at 900° C. and conventional
dry oxidation films formed at 1100° C.

| <100> Tox (Å) | Breakdown Voltage (BV) |
|---|---|
| Inventive Oxides | |
| 458 | −50 |
| 420 | −47 |
| 365 | −39 |
| 277 | −31 |
| Conventional Oxides | |
| 450 | −38 |
| 500 | −30 |

Silicon dioxide films produced according to the present invention exhibit higher breakdown voltages than comparable thickness films produced by conventional techniques of wet and dry oxidation, as well as exhibiting improved batch within-wafer and wafer-to-wafer uniformity as compared to known conventional batch processing techniques.

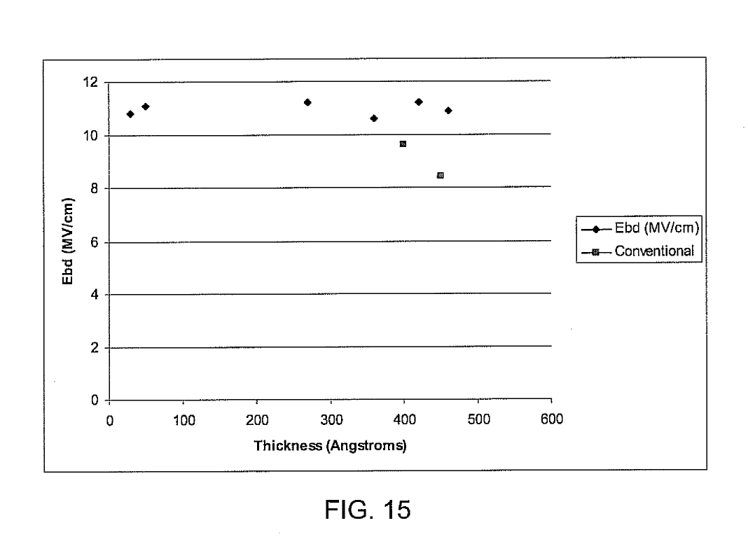

To more easily compare the quality of silicon dioxide formed according to the present invention to that produced by conventional technique, breakdown voltage values obtained from current density as a function of voltage plots are transformed into breakdown electric field plots by dividing breakdown voltage by film thickness and correcting for unit conversion to megavolts per centimeter. After compensating for V_{WF} and V_{Si} as detailed above, a breakdown field essentially independent of film thickness is shown in FIG. 15 with the breakdown electric field associated with inventive silicon dioxide being above 10 MV/cm for all data points with an average value of over 11 MV/cm. The data provided in FIG. 14 is provided on the right portion of FIG. 15.

Within-wafer and wafer-to-wafer uniformity is provided by the inclusion of three planar silicon <100> substrates positioned in substrate carrier positions 2, 25 and 51 with a pitch between substrate carrier positions of 9 millimeters with the wafer being exposed to a process environment and time as detailed above, namely 900° C. process temperature, 1:1 equimolar ratio of hydrogen and oxygen reactants, and 0.2 Torr total process chamber pressure. Each of the three wafer substrates is subjected to profile testing at 25 preselected sites distributed across the wafer surface relative to a wafer indexing notch to provide two-dimensional thickness contour maps. The results of these profile studies are summarized in Table 2 indicating a within-wafer uniformity at 3 σ of less than 1%.

TABLE 2
<100> planar Si wafer thickness profile for inventive process
900° C., H₂:O₂ 1:1, 0.2 Torr

| Wafer Position | Toxₘₐₓ − | Average | WIW | WIW | WIW |
|---|---|---|---|---|---|
| in Carrier | Toxₘᵢₙ (Å) | Tox (Å) | Range | %/σ | %/3σ |
| 2 | 0.6 | 76.29 | 0.81% | 0.28% | 0.85% |
| 25 | 0.8 | 75.08 | 1.10% | 0.30% | 0.91% |
| 51 | 0.7 | 69.32 | 1.06% | 0.32% | 0.96% |

### Example 9

The process of Example 1 is repeated with the replacement of hydrogen as a diatomic reductant source gas by deuterium. Comparable results are obtained with a statistically meaningful increase in oxide deposition rate at a given temperature relative to hydrogen gas.

### Example 10

The procedure of Example 9 is repeated with the process temperature being decreased to 800° C. The breakdown electric field for a variety of film thickness so produced has an average value of slightly over 10 MV/cm for films having a thickness of between 20 and 500 Angstroms after accounting for V_{WF} with the measurement of a gold film and compensation for V_{Si} using the Jackson model provided above.

### Example 11

Throughput substrate processing according to the present invention is estimated by timing the various steps associated with using silicon dioxide alone or in combination with silicon oxynitride coatings of a given thickness at a preselected process temperature. Representative examples are provided in Table 3 with oxidation occurring at a total pressure of 0.92 Torr provided by dual injector flow of equimolar quantities of hydrogen and oxygen, while oxynitridation occurs at a total pressure of 0.92 Torr process environment containing a molar ratio of N₂O:D₂:ND₃ of 2:1:1. Silicon dioxide films produced according to the time-temperature step models of Table 3 are comparable to those characterized in preceding examples. The silicon dioxide films capped with silicon oxynitride are characterized by electrical properties consistent with inventive silicon dioxide with conventional silicon oxynitride surface passivation.

TABLE 3
Throughput models for silicon dioxide or silicon oxynitride
as a function of temperature.

| | Process Temp: | | | | |
|---|---|---|---|---|---|
| | 550 | 600 | 900 | 550 | 900 |
| | Tox (Å): | | | | |
| | 23 | 25 | 38 | 23 | 38 |
| | Ton (Å): | | | | |
| Step, time (min) | — | — | — | 10 | 10 |
| Carrier in, 550° C. | 4 | 4 | 4 | 4 | 4 |
| Ramp up/Pump down | 7 | 7 | 20 | 7 | 20 |
| Stabilize | 15 | 15 | 5 | 15 | 5 |
| Oxidation | 45 | 30 | 15 | 45 | 15 |
| Purge | 2 | 2 | 2 | 2 | 2 |
| Stabilize | — | — | — | 15 | 15 |
| Oxynitridation | — | — | — | 20 | 4 |
| Purge | — | — | — | 2 | 2 |
| Ramp down/Back fill | 9 | 9 | 20 | 9 | 20 |
| Pull, 550° C. | 4 | 4 | 4 | 4 | 4 |
| Carrier exchange | 2 | 2 | 2 | 2 | 2 |
| Total Cycle Time (min) | 88 | 73 | 72 | 115 | 93 |

Patent documents and publications mentioned in the specification are indicative of the levels of those skilled in the art to which the invention pertains. These documents and publications are incorporated herein by reference to the same extent as if each individual document or publication was specifically and individually incorporated herein by reference.

The foregoing description is illustrative of particular embodiments of the invention, but is not meant to be a limitation upon the practice thereof. The following claims, including all equivalents thereof, are intended to define the scope of the invention.

1. A process for forming an oxide-containing film from silicon comprising:
evacuating a process chamber having a vertical extent and containing a plurality of silicon substrates, each of said plurality of silicon substrates having a surface defining a reactive surface plane;
heating said plurality of silicon substrates to a process temperature of between 250° C. and 1100° C. inclusive;
admitting into said process chamber reactants of a diatomic reductant source gas Z-Z′ where Z and Z′ are each independently H, D and T from a first plurality of apertures along the vertical extent of said process chamber;
a stable gas source of oxide ion from a second plurality of apertures along the vertical extent of said process chamber;
providing a plurality of exhaust parts along the vertical extent of said process chamber through which said reactant chamber reactants pass after exposure to the reactive surface plane of each of said plurality of silicon substrates; and
retaining said plurality of silicon substrates in said process chamber at the process temperature for an amount of time sufficient to grow oxide-containing film from silicon.

2. The process of claim 1 wherein said diatomic reductant source gas Z-Z′ attains the reductant partial pressure in the process chamber of between 0.01 and 9 Torr and said stable gas source of oxide ion attains an oxidant partial pressure in said process chamber of between 0.01 and 9 Torr at the process temperature.

3. The process of claim 1 wherein said diatomic reductant source gas and said stable gas source of oxide ion contact the reactive surface plane independent of exposure to an energetic discharge selected from the group consisting of: plasma, actinic radiation and a burner.

4. The process of claim 2 wherein said diatomic reductant source gas and said stable gas source of oxide ion are admitted at a molar ratio of between 0.1:1-4:1.

5. The process of claim 1 wherein the process temperature is less than 400° C.

6. The process of claim 5 wherein said stable gas source of oxide ion is oxygen gas and a total reaction pressure at the process temperature of the reductant partial pressure and the oxidant partial pressure is between 0.2 and 1.5 Torr.

7. The process of claim 1 wherein the temperature is between 350° C. and 650° C.

8. The process of claim 7 wherein the oxide film grows during retention at a growth rate of greater than 0.1 Angstroms per minute.

9. The process of claim 1 wherein the temperature is between 500° C. and 600° C. and the oxide film grows during retention at a growth rate of greater than 0.25 Angstroms per minute.

10. The process of claim 8 wherein the growth rate varies between 2 and 20% between <110> and <100> crystal faces of said plurality of silicon substrates.

11. The process of claim 1 wherein the oxide-containing film is silicon dioxide.

12. The process of claim 1 wherein the oxide-containing film is silicon oxynitride.

13. The process of claim 1 further comprising:
purging said process chamber after growing the oxide-containing film; and
admitting into said process chamber reactants comprising a nitrogen-containing gas source selected from the group consisting of NH₃ and ND₃ alone or in combination with said diatomic reductant gas source and said stable gas source of oxide ion for an amount of time sufficient to grow a silicon oxynitride film overlayer on the oxide-containing film.

14. The process of claim 13 wherein said process chamber is maintained at a pressure of between 0.01 and 30 Torr and a temperature of between 250° C. and 1100° C. inclusive to grow the silicon oxynitride overlayer.

15. A batch of silicon substrates in a substrate carrier comprising:
a plurality of silicon base layers, each of said plurality of silicon base layers having exposed <110> and <100> crystallographic planes; and
a silicon dioxide film formed from each of said plurality of silicon base layers, said film having a residual stress associated with said film being formed at an elevated temperature of less than 600° C. and having a <110> film thickness that exceeds a <100> film thickness on the <100> crystallographic plane by less than 20%.

16. The batch of claim 15 wherein the residual stress is associated with said film being produced at an elevated temperature of greater than 300° C. and less than 400° C.

17. The batch of claim 15 independent of an impurity selected from the group consisting of fluorine, chlorine and carbon.

18. The batch of claim 15 wherein the <110> film thickness exceeds the <100> film thickness by between 5 and 18%.

19. The batch of claim 15 further comprising a silicon oxynitride cap layer overlying and in direct contact with said film.

20. A batch of silicon substrates in a substrate carrier comprising:
a plurality of silicon base layers, each having exposed <110> and <100> crystallographic planes; and
a silicon dioxide film formed from each of said plurality of silicon base layers having a <110> film thickness that exceeds a <100> film thickness by less than 18% and said film is characterized by an electrical breakdown field of greater than 10.5 megavolts per centimeter.

21. The batch of claim 20 wherein the electrical breakdown field is between 10.8 and 11.6 megavolts per centimeter.

22. The batch of claim 21 wherein said film formed on each of said plurality of silicon base layers has a residual stress associated with said film being produced at an elevated temperature of between 800 and 1100° C.

23. The batch of claim 20 wherein said film formed on each of said plurality of silicon base layers has a within-wafer variation in the <100> film thickness at 3 σ of less than 1%.

24. The batch of claim 23 wherein said film formed on each of said plurality of silicon base layers has a thickness variation between the <100> film thickness at 1 σ of less than 1% when the batch exceeds 50 silicon substrates.

25. The batch of claim 20 independent of an impurity selected from the group consisting of fluorine, chlorine and carbon.

26. The batch of claim 20 further comprising a silicon oxynitride cap overlying said film and in contact therewith.
